(19) United States
(12) Patent Application Publication
(10) Pub. No.: US 2026/0045890 A1
(43) Pub. Date: Feb. 12, 2026

(54) POWER CONVERSION CIRCUIT MODULE AND POWER CONVERSION SYSTEM

(71) Applicant: Murata Manufacturing Co., Ltd., Nagaokakyo-shi (JP)

(72) Inventor: Shohei HIROSE, Nagaokakyo-shi (JP)

(21) Appl. No.: 19/362,553

(22) Filed: Oct. 20, 2025

Related U.S. Application Data
(63) Continuation of application No. PCT/JP2024/009590, filed on Mar. 12, 2024.

(30) Foreign Application Priority Data
Apr. 26, 2023 (JP) 2023-072103

(51) Int. Cl. H02M 7/00; H02M 5/458; H05K 1/18

(52) U.S. Cl. CPC H02M 7/00; H02M 5/458; H05K 1/181; H05K 2201/1003

(57) ABSTRACT

A power conversion circuit module includes a coil including first and second coil electrodes, and one or more capacitors each including first and second capacitor electrodes. A mass of the coil is larger than a mass of each of the one or more capacitors. First, second, and third conductors each include a second upper surface and a second lower surface arranged in an up-down direction. Each of the first and second coil electrodes is provided on the second upper surface of the first conductor. The second coil electrode is provided on the second upper surface of the second conductor. The first capacitor electrode is provided on the second upper surface of the third conductor.

### CROSS REFERENCE TO RELATED APPLICATIONS

This application claims the benefit of priority to Japanese Patent Application No. 2023-072103 filed on Apr. 26, 2023 and is a Continuation Application of PCT Application No. PCT/JP2024/009590 filed on Mar. 12, 2024. The entire contents of each application are hereby incorporated herein by reference.

### BACKGROUND OF THE INVENTION

### 1. Field of the Invention

The present invention relates to power conversion circuit modules and power conversion systems.

### 2. Description of the Related Art

As an invention related to a power conversion circuit module in the related art, for example, a DC-DC converter module described in International Publication No. 2015/019519 is known. The DC-DC converter module described in International Publication No. 2015/019519 includes a module substrate, a stud terminal mounted on a surface of the module substrate, and an inductor. The inductor is attached to the stud terminal so as to face the module substrate. For example, the inductor is attached to the stud terminal by soldering. The inductor is electrically coupled to the module substrate with the stud terminal interposed therebetween.

In the field of the DC-DC converter module described in International Publication No. 2015/019519, there is a demand for reducing deviation of an electronic component, such as the inductor, from a desired orientation or a desired position due to heating during soldering or other causes.

### SUMMARY OF THE INVENTION

Example embodiments of the present invention provide power conversion circuit modules and power conversion systems each able to reduce or prevent deviation of an electronic component from a desired orientation or a desired position due to heating during soldering or other causes.

A power conversion circuit module according to an example embodiment of the present invention includes a circuit board including a board main body including an upper main surface and a lower main surface arranged in an up-down direction, and one or more board electrodes on the upper main surface, a coil including a first coil electrode and a second coil electrode, one or more capacitors each including a first capacitor electrode and a second capacitor electrode, a first conductor electrically coupling one of the one or more board electrodes to each of the first coil electrode and the second capacitor electrode, a second conductor electrically coupling another one of the one or more board electrodes to the second coil electrode, and a third conductor electrically coupling another one of the one or more board electrodes to the first capacitor electrode, wherein a mass of the coil is larger than a mass of each of the one or more capacitors, each of the first conductor, the second conductor, and the third conductor includes a second upper surface and a second lower surface arranged in the up-down direction, each of the first coil electrode and the second capacitor electrode is provided on the second upper surface of the first conductor, the second coil electrode is provided on the second upper surface of the second conductor, and the first capacitor electrode is provided on the second upper surface of the third conductor.

A power conversion circuit module according to an example embodiment of the present invention includes a circuit board including a board main body including an upper main surface and a lower main surface arranged in an up-down direction and one or more board electrodes on the upper main surface, a coil including a first coil electrode, and a first conductor electrically coupling one of the one or more board electrodes to the first coil electrode, wherein the first conductor includes a plate-shaped portion extending in a front-back direction and including a first upper surface and a first lower surface arranged in the up-down direction, a first support portion extending in a down direction from a rear end portion of the first lower surface, and a second support portion extending in the down direction from a front end portion of the first lower surface, when seen in the down direction, the first upper surface of the first conductor includes a first region not overlapping one of the first support portion of the first conductor and the second support portion of the first conductor, at least one of the first support portion of the first conductor or the second support portion of the first conductor is provided on the one of the one or more board electrodes, and at least a portion of the first coil electrode is provided on the first region.

The power conversion circuit modules according to example embodiments of the present invention are each able to reduce or prevent deviation of an electronic component from a desired orientation or a desired position due to heating during soldering or other causes.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 illustrates an example of a basic circuit of a buck converter.

FIG. 2 illustrates an example of a basic circuit of a three-phase-motor driving device.

FIG. 3 is a perspective view of a circuit module 1 according to a first example embodiment of the present invention.

FIG. 4 is a perspective view of a circuit board 2 according to the first example embodiment of the present invention.

FIG. 5 is a perspective view of a first conductor 3 (a second conductor 4 or a third conductor 5) according to the first example embodiment of the present invention.

FIG. 6 is a perspective view of a coil 6 according to the first example embodiment of the present invention.

FIG. 7 is a perspective view of a capacitor 7a according to the first example embodiment of the present invention.

FIG. 8 is a plan view of the circuit module 1 according to the first example embodiment of the present invention when seen in a down direction.

FIG. 9 is a side view of a circuit module 100 according to a comparative example before, during, and after reflow heating when seen in a front direction.

FIG. 10 is a side view of the circuit module 1 according to the first example embodiment of the present invention before, during, and after reflow heating when seen in the front direction.

FIG. 11 is a sectional view of the circuit module 1 according to the first example embodiment of the present invention during and after reflow heating when seen in a left direction.

FIG. 12 is a sectional view of the circuit module 1 according to the first example embodiment of the present invention during and after reflow heating when seen in a right direction.

FIG. 13 is a perspective view of the circuit board 2 according to a first modification of an example embodiment of the present invention.

FIG. 14 is a perspective view of the circuit board 2 according to a second modification of an example embodiment of the present invention.

FIG. 15 is a plan view of a circuit module 1c according to a third modification of an example embodiment of the present invention when seen in the down direction.

FIG. 16 is a perspective view of the first conductor 3 according to a fourth modification of an example embodiment of the present invention.

FIG. 17 is a perspective view of the first conductor 3 (the second conductor 4 or the third conductor 5) according to a fifth modification of an example embodiment of the present invention.

FIG. 18 is a sectional view of the first conductor 3 (the second conductor 4 or the third conductor 5) according to the fifth modification when seen in the right direction.

FIG. 19 is a plan view of a circuit module 1e according to the fifth modification when seen in the down direction.

FIG. 20 is a perspective view of the first conductor 3 (the second conductor 4 or the third conductor 5) according to a sixth modification of an example embodiment of the present invention.

FIG. 21 is a sectional view of the first conductor 3 (the second conductor 4 or the third conductor 5) according to the sixth modification when seen in the right direction.

FIG. 22 is a sectional view of the second conductor 4 according to a seventh modification of an example embodiment of the present invention when seen in the right direction.

### DETAILED DESCRIPTION OF THE EXAMPLE EMBODIMENTS

Example embodiments of the present invention will be described in detail below with reference to the drawings.

### First Example Embodiment

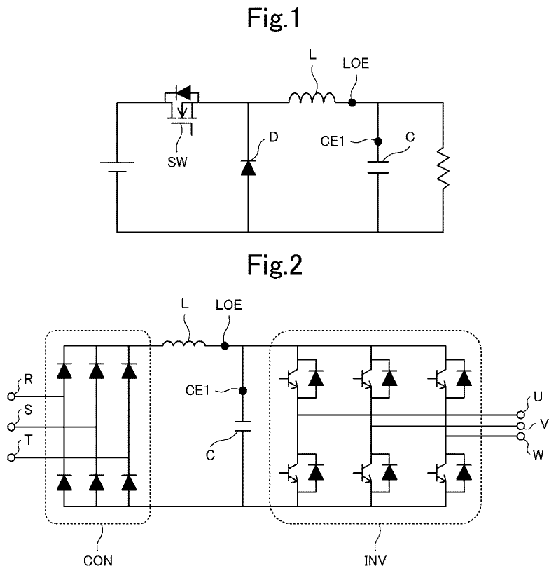

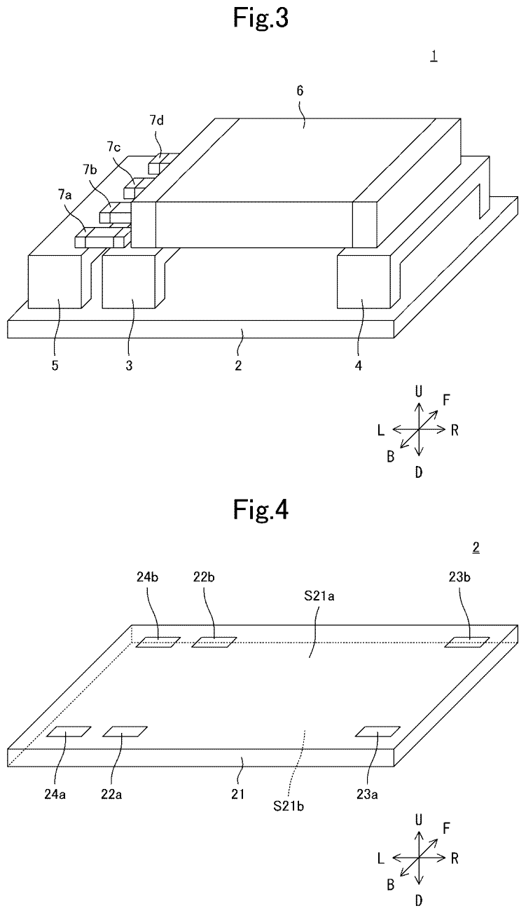

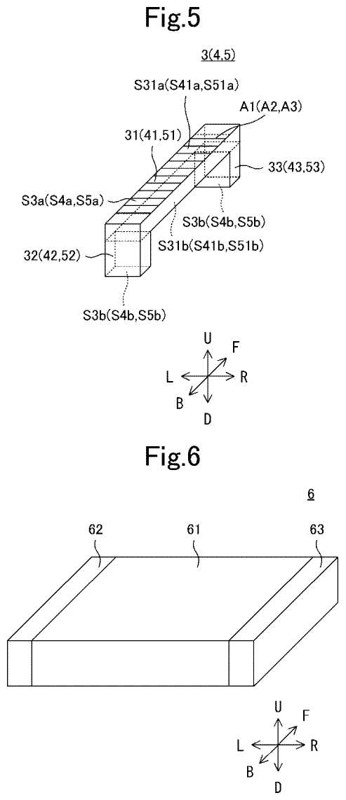

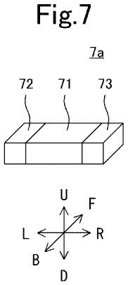

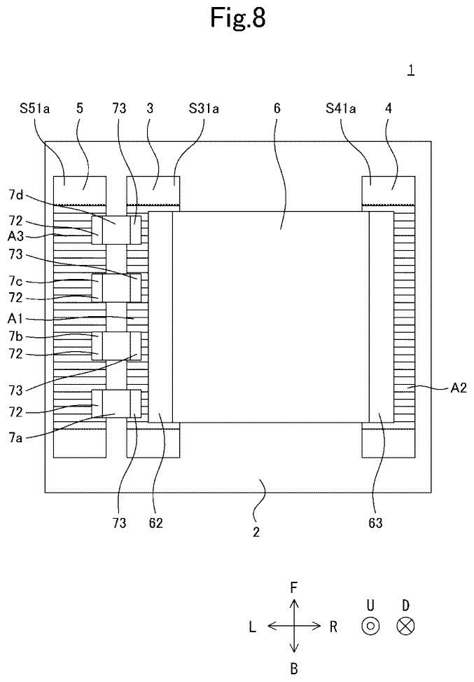

Hereinafter, a circuit module 1 according to a first example embodiment of the present invention is described with reference to the drawings. FIG. 1 illustrates an example of a basic circuit of a buck converter. FIG. 2 illustrates an example of a basic circuit of a three-phase-motor driving device. FIG. 3 is a perspective view of the circuit module 1 according to the first example embodiment. FIG. 4 is a perspective view of a circuit board 2 according to the first example embodiment. FIG. 5 is a perspective view of a first conductor 3 (a second conductor 4 or a third conductor 5) according to the first example embodiment. FIG. 6 is a perspective view of a coil 6 according to the first example embodiment. FIG. 7 is a perspective view of a capacitor 7a according to the first example embodiment. FIG. 8 is a plan view of the circuit module 1 according to the first example embodiment when seen in a down direction.

Herein, directions are defined follows. As illustrated in FIG. 3, a direction in which the coil 6 and the circuit board 2 are arranged in this order is defined as a down direction. A direction opposite to the down direction is defined as an up direction. A direction in which a second support portion 33 of the first conductor 3 and a first support portion 32 of the first conductor 3 are arranged in this order is defined as a back direction. A direction opposite to the back direction is defined as a front direction. Each of the back direction and the front direction is orthogonal or substantially orthogonal to the down direction. A direction in which the second conductor 4 and the first conductor 3 are arranged in this order is defined as a left direction. A direction opposite to the left direction is defined as a right direction. Each of the left direction and the right direction is orthogonal or substantially orthogonal to the down direction and the back direction. However, the down direction, the up direction, the back direction, the front direction, the left direction, and the right direction herein are directions defined for convenience of explanation, and do not necessarily match a down direction, an up direction, a back direction, a front direction, a left direction, and a right direction in use of the circuit module 1. Moreover, in each drawing, the down direction and the up direction are interchangeable, the back direction and the front direction are interchangeable, and the left direction and the right direction are interchangeable.

Herein, a positional relationship between members is defined as follows. The circuit module 1 includes first to third members. Herein, a state in which the first member is disposed on or above the second member indicates the following state. At least a portion of the first member is located immediately on or above the second member. Therefore, when seen in the down direction, the first member overlaps the second member. This definition is also applicable to the directions other than the up direction.

Herein, a state in which the first member is disposed higher than the second member includes a case in which at least a portion of the first member is located immediately above the second member as well as a case in which the first member is not located immediately above the second member but is located diagonally above the second member. In this case, when seen in the down direction, the first member does not necessarily overlap the second member. The diagonally above includes, for example, an upper left and an upper right. This definition is also applicable to the directions other than the up direction.

Herein, each portion of the first member is defined as follows unless otherwise described. A front portion of the first member means a front half of the first member. A front end of the first member means an end of the first member in the front direction. A front end portion of the first member means the front end and its vicinity of the first member. This definition is also applicable to the directions other than the front direction. Moreover, a corner portion of the first member means a corner and its vicinity of the first member.

Herein, when any two members are defined as the first member and the second member, a relationship of the two members is as follows. Herein, a state in which the first member is supported by the second member includes a case in which the first member is attached to (that is, fixed to) the second member so as not to be movable with respect to the second member as well as a case in which the first member is attached to the second member so as to be movable with respect to the second member. Further, the state in which the first member is supported by the second member includes both a case in which the first member is directly attached to the second member and a case in which the first member is attached to the second member with the third member interposed therebetween.

Herein, “the first member and the second member are electrically coupled to one another” means that the first member and the second member are electrically conductive to one another. Therefore, the first member and the second member are either in contact with or not in contact with one another. In the case in which the first member and the second member are not in contact with one another, the third member having conductivity is disposed between the first member and the second member.

Herein, a member extending in an up-down direction is a member inclined within a range of about ±45° with respect to the up-down direction. Similarly, a member extending in a front-back direction does not necessarily indicate only a member parallel or substantially parallel to the front-back direction. The member extending in the front-back direction is a member inclined within a range of about ±45° with respect to the front-back direction. A member extending in a left-right direction is a member inclined within a range of about ±45° with respect to the left-right direction.

For example, the circuit module 1 is used in a power conversion device, such as a buck converter, for example. The buck converter is an example of a power conversion device. As illustrated in FIG. 1, the buck converter includes an inductor L and a capacitor C. The capacitor C is an output capacitor of the buck converter. In the basic circuit of the buck converter illustrated in FIG. 1, an output end LOE of the inductor L has the same potential as a first end CE1 of the capacitor C. The circuit module 1 corresponds to a “power conversion circuit module”.

For example, the circuit module 1 may be used in a three-phase-motor driving device that drives a three-phase motor. As illustrated in FIG. 2, the three-phase-motor driving device includes a rectifier CON, an inductor L, a capacitor C, and an inverter INV. For example, a three-phase AC power supply is coupled to input ends R, S, and T of the three-phase-motor driving device. For example, a three-phase induction motor is coupled to output ends U, V, and W of the three-phase-motor driving device. In the basic circuit of the three-phase-motor driving device illustrated in FIG. 2, an output end LOE of the inductor L has the same potential as a first end CE1 of the capacitor C. In this way, the circuit module 1 is used in a power conversion device.

As illustrated in FIG. 3, the circuit module 1 includes a circuit board 2, a first conductor 3, a second conductor 4, a third conductor 5, a coil 6, and capacitors 7a, 7b, 7c, and 7d.

As illustrated in FIG. 4, the circuit board 2 includes a board main body 21, first board electrodes 22a and 22b, second board electrodes 23a and 23b, and third board electrodes 24a and 24b. The board main body 21 includes an upper main surface S21a and a lower main surface S21b arranged in the up-down direction. The board main body 21 has a rectangular or substantially rectangular shape when seen in the down direction. A material for the board main body 21 is, for example, glass epoxy. An electric circuit including a conductive layer (not illustrated) is provided inside of the upper main surface S21a, inside of the lower main surface S21b, and inside of the board main body 21. Each of the first board electrodes 22a and 22b, the second board electrodes 23a and 23b, and the third board electrodes 24a and 24b corresponds to a “board electrode”.

Each of the first board electrodes 22a and 22b, the second board electrodes 23a and 23b, and the third board electrodes 24a and 24b is provided on the upper main surface S21a. In the present example embodiment, the first board electrodes 22a and 22b are arranged in this order from the back to the front. The second board electrodes 23a and 23b are arranged in this order from the back to the front. The third board electrodes 24a and 24b are arranged in this order from the back to the front. In the present example embodiment, the first board electrodes 22a and 22b are electrically coupled to one another through a conductive layer (not illustrated). The second board electrodes 23a and 23b are electrically coupled to one another through a conductive layer (not illustrated). The third board electrodes 24a and 24b are electrically coupled to one another through a conductive layer (not illustrated).

The third board electrode 24a, the first board electrode 22a, and the second board electrode 23a are arranged in this order from the left to the right when seen in the front direction. The third board electrode 24b, the first board electrode 22b, and the second board electrode 23b are arranged in this order from the left to the right when seen in the front direction. In the present example embodiment, the third board electrode 24a, the first board electrode 22a, and the second board electrode 23a are arranged in this order from the left to the right. The third board electrode 24b, the first board electrode 22b, and the second board electrode 23b are arranged in this order from the left to the right.

The first conductor 3 is provided on the first board electrodes 22a and 22b. The second conductor 4 is provided on the second board electrodes 23a and 23b. The third conductor 5 is provided on the third board electrodes 24a and 24b. Therefore, as illustrated in FIG. 3, the third conductor 5, the first conductor 3, and the second conductor 4 are arranged in this order from the left to the right when seen in the front direction. In the present example embodiment, the third conductor 5, the first conductor 3, and the second conductor 4 are arranged in this order from the left to the right. A material for each of the first conductor 3, the second conductor 4, and the third conductor 5 is, for example, metal. The metal is, for example, copper. Each of the first conductor 3, the second conductor 4, and the third conductor 5 has conductivity.

Structures of the first conductor 3, the second conductor 4, and the third conductor 5 of the present example embodiment are described in detail with reference to the drawings. The structures of the second conductor 4 and the third conductor 5 are the same or substantially the same as the structure of the first conductor 3, and thus description of the structures of the second conductor 4 and the third conductor 5 is omitted.

As illustrated in FIG. 5, the first conductor 3 includes a plate-shaped portion 31, a first support portion 32, and a second support portion 33. The plate-shaped portion 31 includes a first upper surface S31a and a first lower surface S31b arranged in the up-down direction. The plate-shaped portion 31 extends in the front-back direction. In more detail, in the present example embodiment, the plate-shaped portion 31 has a rectangular or substantially rectangular shape including left and right sides extending in the front-back direction and back and front sides extending in the left-right direction when seen in the down direction. The plate-shaped portion 31 has flexibility.

The first support portion 32 extends in the down direction from a rear end portion of the first lower surface S31b. In the present example embodiment, the first support portion 32 has a rectangular or substantially rectangular parallelepiped shape. The first support portion 32 supports a rear portion of the plate-shaped portion 31. The first support portion 32 is provided on the first board electrode 22a. In more detail, for example, a lower surface of the first support portion 32 is fixed onto the first board electrode 22a by solder (not illustrated). Therefore, the first conductor 3 is electrically coupled to the first board electrode 22a.

The second support portion 33 extends in the down direction from a front end portion of the first lower surface S31b. In the present example embodiment, the second support portion 33 has a rectangular or substantially rectangular parallelepiped shape. The second support portion 33 supports a front portion of the plate-shaped portion 31. The second support portion 33 is provided on the first board electrode 22b. In more detail, for example, a lower surface of the second support portion 33 is fixed onto the first board electrode 22b by solder (not illustrated). Therefore, the first conductor 3 is electrically coupled to the first board electrode 22b.

The first upper surface S31a includes a first region A1 not overlapping one of the first support portion 32 and the second support portion 33 when seen in the down direction. In the present example embodiment, the first upper surface S31a includes the first region A1 not overlapping either of the first support portion 32 or the second support portion 33 when seen in the down direction.

The first conductor 3 includes a second upper surface S3a and a second lower surface S3b arranged in the up-down direction. In the present example embodiment, the second upper surface S3a is the first upper surface S31a of the plate-shaped portion 31. The second lower surface S3b is the lower surface of the first support portion 32 and the lower surface of the second support portion 33. The second lower surface S3b is provided on the first board electrodes 22a and 22b. In more detail, for example, the second lower surface S3b is fixed onto the first board electrodes 22a and 22b by solder (not illustrated).

Similarly to the first conductor 3, the second conductor 4 includes a plate-shaped portion 41, a first support portion 42, and a second support portion 43. The plate-shaped portion 41 corresponds to the plate-shaped portion 31. Therefore, the plate-shaped portion 41 includes a first upper surface S41a and a first lower surface S41b arranged in the up-down direction. The plate-shaped portion 41 has flexibility. Further, the first support portion 42 corresponds to the first support portion 32. Therefore, the first support portion 42 is provided on the second board electrode 23a. Further, the second support portion 43 corresponds to the second support portion 33. Therefore, the second support portion 43 is provided on the second board electrode 23b. The first upper surface S41a includes a second region A2 not overlapping one of the first support portion 42 and the second support portion 43 when seen in the down direction. In the present example embodiment, the first upper surface S41a includes the second region A2 not overlapping either the first support portion 42 or the second support portion 43 when seen in the down direction.

In addition, the second conductor 4 includes a second upper surface S4a and a second lower surface S4b arranged in the up-down direction. The second upper surface S4a is the first upper surface S41a of the plate-shaped portion 41. The second lower surface S4b is a lower surface of the first support portion 42 and a lower surface of the second support portion 43. The second lower surface S4b is provided on the second board electrodes 23a and 23b. In more detail, for example, the second lower surface S4b is fixed onto the second board electrodes 23a and 23b by solder (not illustrated).

Similarly to the first conductor 3, the third conductor 5 includes a plate-shaped portion 51, a first support portion 52, and a second support portion 53. The plate-shaped portion 51 corresponds to the plate-shaped portion 31. Therefore, the plate-shaped portion 51 includes a first upper surface S51a and a first lower surface S51b arranged in the up-down direction. The plate-shaped portion 51 has flexibility. Further, the first support portion 52 corresponds to the first support portion 32. Therefore, the first support portion 52 is provided on the third board electrode 24a. Further, the second support portion 53 corresponds to the second support portion 33. Therefore, the second support portion 53 is provided on the third board electrode 24b. The first upper surface S51a includes a third region A3 not overlapping one of the first support portion 52 and the second support portion 53 when seen in the down direction. In the present example embodiment, the first upper surface S51a includes the third region A3 not overlapping either the first support portion 52 or the second support portion 53 when seen in the down direction.

In addition, the third conductor 5 includes a second upper surface S5a and a second lower surface S5b arranged in the up-down direction. The second upper surface S5a is the first upper surface S51a of the plate-shaped portion 51. The second lower surface S5b is a lower surface of the first support portion 52 and a lower surface of the second support portion 53. The second lower surface S5b is provided on the third board electrodes 24a and 24b.

As illustrated in FIG. 6, the coil 6 includes a main body 61, a first coil electrode 62, and a second coil electrode 63. In the present example embodiment, the main body 61 has a rectangular or substantially rectangular parallelepiped shape. The first coil electrode 62 and the second coil electrode 63 are provided to a surface of the main body 61. The first coil electrode 62 and the second coil electrode 63 are arranged in this order from the left to the right when seen in the front direction. In the present example embodiment, the first coil electrode 62 and the second coil electrode 63 are arranged in this order from the left to the right.

The first coil electrode 62 is provided on the second upper surface S3a of the first conductor 3. In more detail, for example, the first coil electrode 62 is fixed onto the second upper surface S3a by solder (not illustrated). Accordingly, the first coil electrode 62 is electrically coupled to the first conductor 3. Therefore, the first coil electrode 62 is electrically coupled to the first board electrodes 22a and 22b by the first conductor 3.

The second coil electrode 63 is provided on the second upper surface S4a of the second conductor 4. In more detail, for example, the second coil electrode 63 is fixed onto the second upper surface S4a by solder (not illustrated). Accordingly, the second coil electrode 63 is electrically coupled to the second conductor 4. Therefore, the second coil electrode 63 is electrically coupled to the second board electrodes 23a and 23b by the second conductor 4. The coil 6 corresponds to the inductor L in FIG. 1 or FIG. 2.

As illustrated in FIG. 7, the capacitor 7a includes a main body 71, a first capacitor electrode 72, and a second capacitor electrode 73. The main body 71 has a rectangular or substantially rectangular parallelepiped shape. The first capacitor electrode 72 and the second capacitor electrode 73 are provided on a surface of the main body 71. In the present example embodiment, the first capacitor electrode 72 and the second capacitor electrode 73 are arranged in this order from the left to the right.

The first capacitor electrode 72 is provided on the second upper surface S5a of the third conductor 5. In more detail, for example, the first capacitor electrode 72 is fixed onto the second upper surface S5a by solder (not illustrated). Accordingly, the first capacitor electrode 72 is electrically coupled to the third conductor 5. Therefore, the first capacitor electrode 72 is electrically coupled to the third board electrodes 24a and 24b by the third conductor 5.

The second capacitor electrode 73 is provided on the second upper surface S3a of the first conductor 3. In more detail, for example, the second capacitor electrode 73 is fixed onto the second upper surface S3a by solder (not illustrated). Accordingly, the second capacitor electrode 73 is electrically coupled to the first conductor 3. Therefore, the second capacitor electrode 73 is electrically coupled to the first board electrodes 22a and 22b by the first conductor 3.

A mass of the capacitor 7a is smaller than a mass of the coil 6. In other words, the mass of the coil 6 is larger than the mass of the capacitor 7a. Structures of the capacitors 7b, 7c, and 7d are the same or substantially the same as a structure of the capacitor 7a, and thus description of the structures of the capacitors 7b, 7c, and 7d is omitted. The capacitors 7a, 7b, 7c, and 7d correspond to the capacitor C in FIG. 1 or FIG. 2. That is, in the present example embodiment, the capacitors 7a, 7b, 7c, and 7d are connected in parallel, thus defining the capacitor C in FIG. 1 or FIG. 2.

Positions of the first conductor 3, the second conductor 4, the third conductor 5, the coil 6, and the capacitors 7a, 7b, 7c, and 7d of the present example embodiment are described in detail with reference to the drawings.

As illustrated in FIG. 8, the capacitors 7a, 7b, 7c, and 7d are arranged in the front-back direction. Specifically, the capacitors 7a, 7b, 7c, and 7d are arranged in this order in a row from the back to the front. Moreover, the first capacitor electrode 72, the second capacitor electrode 73, the first coil electrode 62, and the second coil electrode 63 are arranged in this order from the left to the right when seen in the front direction. Specifically, the first capacitor electrode 72, the second capacitor electrode 73, the first coil electrode 62, and the second coil electrode 63 are arranged in this order in a row from the left to the right.

At least a portion of the first coil electrode 62 is provided on the first region A1 of the first upper surface S31a. Therefore, at least a portion of the first coil electrode 62 overlaps the first region A1 when seen in the down direction. In the present example embodiment, the entirety or substantially the entirety of the first coil electrode 62 is provided on the first region A1 of the first upper surface S31a.

At least a portion of the second coil electrode 63 is provided on the second region A2 of the first upper surface S41a. Therefore, at least a portion of the second coil electrode 63 overlaps the second region A2 when seen in the down direction. In the present example embodiment, the entirety or substantially the entirety of the second coil electrode 63 is provided on the second region A2 of the first upper surface S41a.

At least a portion of the first capacitor electrode 72 is provided on the third region A3 of the first upper surface S51a. Therefore, at least a portion of the first capacitor electrode 72 overlaps the third region A3 when seen in the down direction. In the present example embodiment, the entirety or substantially an entirety of the first capacitor electrode 72 is provided on the third region A3 of the first upper surface S51a.

At least a portion of the second capacitor electrode 73 is provided on the first region A1 of the first upper surface S31a. Therefore, at least a portion of the second capacitor electrode 73 overlaps the first region A1 when seen in the down direction. In the present example embodiment, the entirety or substantially the entirety of the second capacitor electrode 73 is provided on the first region A1 of the first upper surface S31a.

### Advantageous Effects

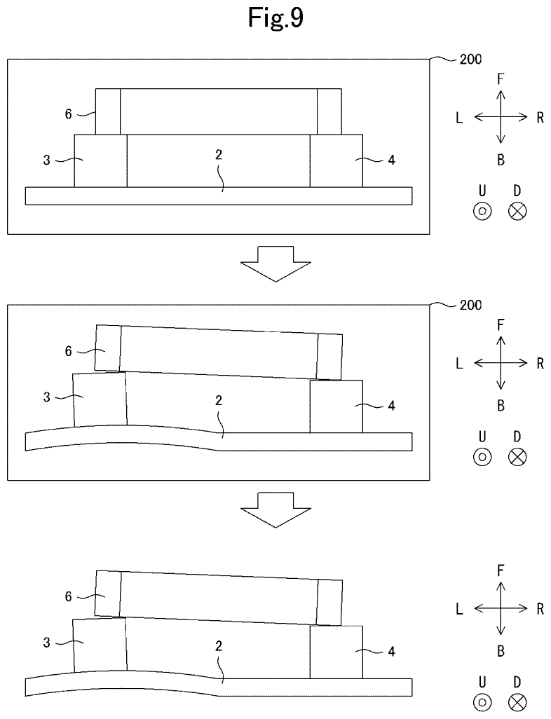

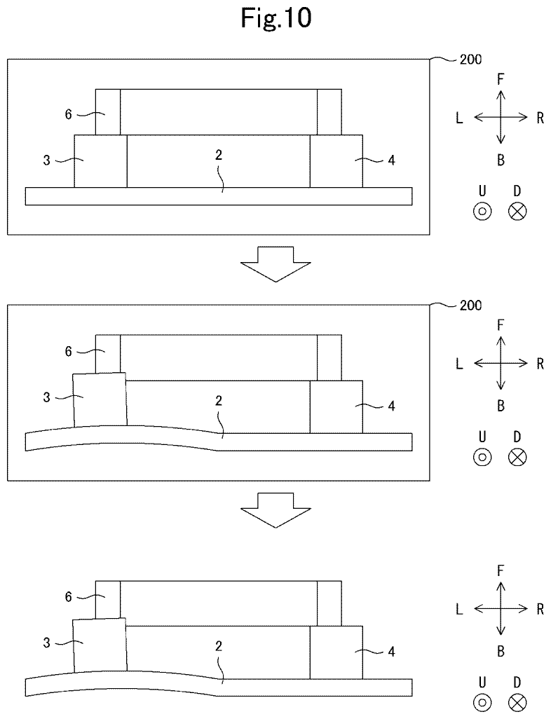

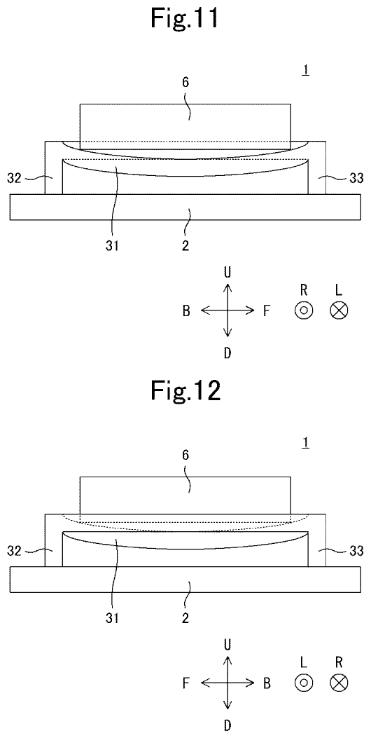

The circuit module 1 can reduce or prevent deviation of an electronic component from a desired orientation or a desired position due to heating during soldering. Specifically, the circuit module 1 can reduce or prevent deviation of an electronic component from a desired orientation due to heating during soldering. In the present example embodiment, the electronic component is the coil 6 or each of the capacitors 7a, 7b, 7c, and 7d. Description is provided using the coil 6 as an example. First, a circuit module 100 is described as a comparative example. The circuit module 100 does not include the third conductor 5 or the capacitors 7a, 7b, 7c, and 7d, and each of the first conductor 3 and the second conductor 4 has a rectangular or substantially rectangular parallelepiped shape extending in the front-back direction. FIG. 9 is a plan view of the circuit module 100 according to the comparative example before, during, and after reflow heating when seen in the front direction. FIG. 10 is a plan view of the circuit module 1 according to the first example embodiment before, during, and after reflow heating when seen in the front direction. FIG. 11 is a sectional view of the circuit module 1 according to the first example embodiment during and after reflow heating when seen in the left direction. FIG. 12 is a sectional view of the circuit module 1 according to the first example embodiment during and after reflow heating when seen in the right direction.

When soldering is performed to the circuit module 100 according to the comparative example (hereinafter, simply referred to as the circuit module 100), the circuit board 2, the first conductor 3, the second conductor 4, and the coil 6 are introduced into a reflow oven 200 (FIG. 9: top figure), and the circuit board 2, the first conductor 3, the second conductor 4, and the coil 6 are heated. The circuit board 2 expands due to heating.

At this time, for example, in a case in which a volume ratio of a conductor layer provided to a left portion of the circuit board 2 to the entire or substantially the entire left portion of the circuit board 2 differs from a volume ratio of a conductor layer provided to a right portion of the circuit board 2 to the entire or substantially the entire right portion of the circuit board 2, a coefficient of linear expansion of the left portion of the circuit board 2 differs from a coefficient of linear expansion of the right portion of the circuit board 2. For example, in a case in which the volume ratio of the conductor layer provided to the left portion of the circuit board 2 to the entire or substantially the entire left portion of the circuit board 2 is less than the volume ratio of the conductor layer provided to the right portion of the circuit board 2 to the entire or substantially the entire right portion of the circuit board 2, the coefficient of linear expansion of the left portion of the circuit board 2 is higher than the coefficient of linear expansion of the right portion of the circuit board 2. Therefore, the left portion of the circuit board 2 warps in the up-down direction more easily than the right portion of the circuit board 2 (FIG. 9: middle figure). Accordingly, each of the first conductor 3 and the coil 6 inclines.

Glass epoxy, which is an example of the material for the board main body 21, has characteristics of hardening due to heating. Therefore, even after the circuit board 2, the first conductor 3, the second conductor 4, and the coil 6 are removed from the reflow oven 200, the first conductor 3 and the coil 6 remain inclined (FIG. 9: bottom figure).

With respect to this, in the circuit module 1, the first upper surface S31a includes the first region A1 not overlapping one of the first support portion 32 and the second support portion 33 when seen in the down direction. At least a portion of the first coil electrode 62 is provided on the first region A1 of the first upper surface S31a. Accordingly, as illustrated in FIGS. 11 and 12, when seen in the down direction, a portion of the plate-shaped portion 31 overlapping the at least a portion of the first coil electrode 62 bends in the down direction due to a load received from the coil 6. As a result, as illustrated in FIG. 10, even when the first conductor 3 inclines, the coil 6 can remain horizontal or substantially horizontal.

Similarly, for example, in a case in which the volume ratio of the conductor layer provided to the right portion of the circuit board 2 to the entire or substantially the entire right portion of the circuit board 2 is less than the volume ratio of the conductor layer provided to the left portion of the circuit board 2 to the entire or substantially the entire left portion of the circuit board 2, the coefficient of linear expansion of the right portion of the circuit board 2 is higher than the coefficient of linear expansion of the left portion of the circuit board 2. In this case, the right portion of the circuit board 2 warps in the up-down direction more easily than the left portion of the circuit board 2. In the circuit module 1, the first upper surface S41a includes the second region A2 not overlapping one of the first support portion 42 and the second support portion 43 when seen in the down direction. At least a portion of the second coil electrode 63 is provided on the second region A2 of the first upper surface S41a. Accordingly, when seen in the down direction, a portion of the plate-shaped portion 41 overlapping the at least a portion of the second coil electrode 63 bends in the down direction due to a load received from the coil 6. As a result, even when the second conductor 4 inclines, the coil 6 can remain horizontal or substantially horizontal. Therefore, the circuit module 1 can reduce or prevent deviation of the coil 6 from the horizontal posture due to heating during soldering. Thus, the circuit module 1 can reduce or prevent deviation of the coil 6 from a desired orientation due to heating during soldering. As a result, the circuit module 1 can reduce or prevent deviation of an electronic component from a desired orientation or a desired position due to heating during soldering.

In addition, the circuit module 1 can reduce or prevent a decrease in an inductance value of the coil 6. In more detail, a volume of each of the first conductor 3 and the second conductor 4 in the circuit module 1 is smaller than a volume of each of the first conductor 3 and the second conductor 4 in the circuit module 100. Therefore, an eddy current caused to each of the first conductor 3 and the second conductor 4 in the circuit module 1 by magnetic flux generated by the coil 6 is smaller than an eddy current caused to each of the first conductor 3 and the second conductor 4 in the circuit module 100 by magnetic flux generated by the coil 6. The eddy current caused to each of the first conductor 3 and the second conductor 4 flows in a direction to offset the magnetic flux generated by the coil 6. Therefore, a decrease in an inductance value of the coil 6 due to the eddy current caused to each of the first conductor 3 and the second conductor 4 in the circuit module 1 is smaller than a decrease in an inductance value of the coil 6 due to the eddy current caused to each of the first conductor 3 and the second conductor 4 in the circuit module 100. As a result, the circuit module 1 can reduce or prevent a decrease in the inductance value of the coil 6.

In addition, the circuit module 1 can reduce or prevent deviation of the capacitor 7a from a desired position due to heating during soldering. In more detail, when soldering is performed to the circuit module 1, the circuit board 2, the first conductor 3, the second conductor 4, the third conductor 5, the coil 6, and the capacitors 7a, 7b, 7c, and 7d are introduced into the reflow oven 200, and the circuit board 2, the first conductor 3, the second conductor 4, the third conductor 5, the coil 6, and the capacitors 7a, 7b, 7c, and 7d are heated.

At this time, solder provided on each of the second upper surface S3a, the second upper surface S4a, and the second upper surface S5a is melted by heating. Accordingly, each of the capacitor 7a and the coil 6 may slide on the melted solder and be deviated from the position before the heating. In this manner, each of the capacitor 7a and the coil 6 may deviate from a desired position due to heating during soldering. With regard to this, the mass of the coil 6 is larger than the mass of the capacitor 7a. Therefore, positional deviation of the coil 6 is reduced or prevented as compared with positional deviation of the capacitor 7a. Moreover, positional deviation of the capacitor 7a in the right direction is obstructed by the coil 6. Therefore, the circuit module 1 can reduce or prevent deviation of the capacitor 7a from the position before the heating. As a result, the circuit module 1 can reduce deviation of the capacitor 7a from a desired position due to heating during soldering. This is applicable not only to the capacitor 7a, but also to the capacitors 7b, 7c, and 7d in the same or similar manner.

In addition, the circuit module 1 can make the capacitors 7a, 7b, 7c, and 7d less likely to break down. In more detail, the capacitors 7a, 7b, 7c, and 7d are arranged in the front-back direction. The first capacitor electrodes 72 of the respective ones of the capacitors 7a, 7b, 7c, and 7d have the same potential as each other. Moreover, the second capacitor electrodes 73 of the respective ones of the capacitors 7a, 7b, 7c, and 7d have the same potential as each other. Therefore, even when each of the capacitors 7a, 7b, 7c, and 7d slides on solder melted by heating and moves in the front-back direction, and the first capacitor electrodes 72 of the respective ones of the capacitors 7a, 7b, 7c, and 7d or the second capacitor electrodes 73 of the respective ones of the capacitors 7a, 7b, 7c, and 7d contact one another, the capacitors 7a, 7b, 7c, and 7d do not break down. Therefore, the circuit module 1 can make the capacitors 7a, 7b, 7c, and 7d less likely to break down.

### First Modification

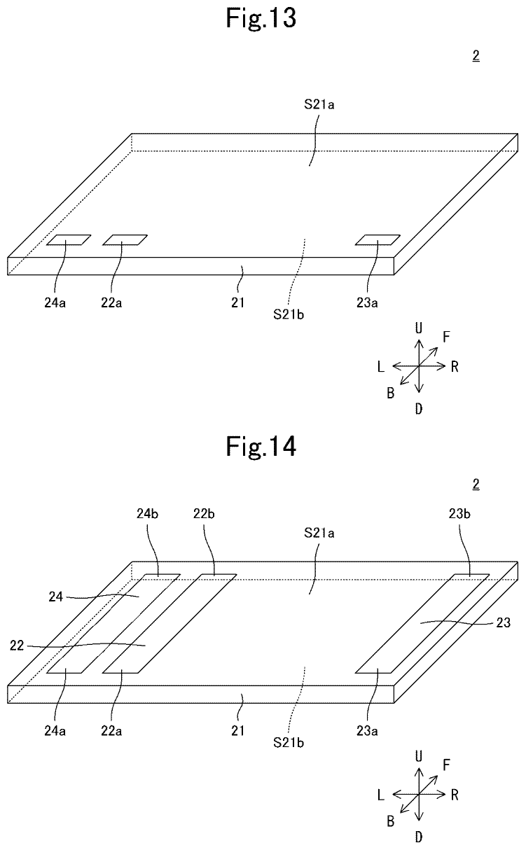

Below, a structure of a circuit module 1a according to a first modification of an example embodiment of the present invention is described with reference to the drawing. FIG. 13 is a perspective view of the circuit board 2 according to the first modification. The circuit module 1a according to the first modification is described only about a portion different from that of the circuit module 1 according to the first example embodiment, and description of the other portions is omitted.

The circuit module 1a according to the first modification is different from the circuit module 1 according to the first example embodiment in that the circuit board 2 does not include the first board electrode 22b, the second board electrode 23b, and the third board electrode 24b.

Each of the second support portion 33, the second support portion 43, and the second support portion 53 is provided on the upper main surface S21a where the first board electrode 22a, the second board electrode 23a, and the third board electrode 24a are not provided.

The circuit module 1a as described above also achieves the same or substantially the same advantageous effects as those of the circuit module 1. Also in a case in which the circuit board 2 does not include the first board electrode 22a, the second board electrode 23a, and the third board electrode 24a, and includes the first board electrode 22b, the second board electrode 23b, and the third board electrode 24b, the same or substantially the same advantageous effects as those of the circuit module 1 are achieved. That is, the number of first board electrodes is one or more. The number of second board electrodes is one or more. The number of third board electrodes is one or more.

### Second Modification

Below, a structure of a circuit module 1b according to a second modification of an example embodiment of the present invention is described with reference to the drawing. FIG. 14 is a perspective view of the circuit board 2 according to the second modification. The circuit module 1b according to the second modification is described only about a portion different from that of the circuit module 1 according to the first example embodiment, and description of the other portions is omitted.

The circuit module 1b according to the second modification is different from the circuit module 1 according to the first example embodiment in that the first board electrode 22a and the first board electrode 22b are connected to one another, the second board electrode 23a and the second board electrode 23b are connected to one another, and the third board electrode 24a and the third board electrode 24b are connected to one another.

The circuit module 1b as described above also achieves the same or substantially the same advantageous effects as those of the circuit module 1. As described in this modification, the first board electrodes 22a and 22b may be included in a single first board electrode 22. The second board electrodes 23a and 23b may be included in a single second board electrode 23. The third board electrodes 24a and 24b may be included in a single third board electrode 24.

### Third Modification

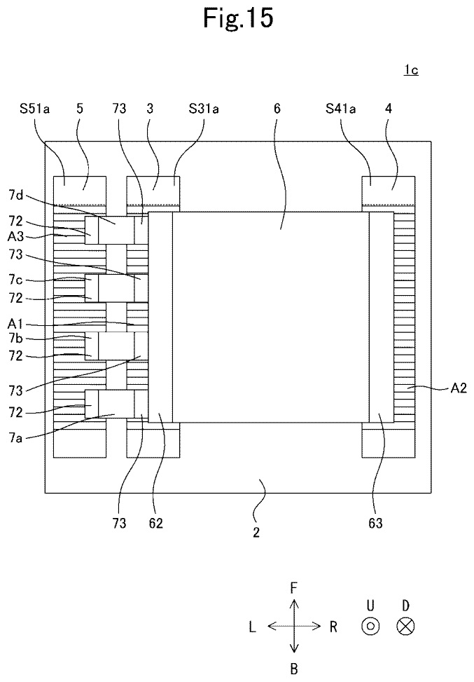

Below, a structure of a circuit module 1c according to a third modification of an example embodiment of the present invention is described with reference to the drawing. FIG. 15 is a plan view of the circuit module 1c according to the third modification when seen in the down direction. The circuit module 1c according to the third modification is described only about a portion different from that of the circuit module 1 according to the first example embodiment, and description of the other portions is omitted.

The circuit module 1c according to the third modification is different from the circuit module 1 according to the first example embodiment in that the capacitors 7a, 7b, 7c, and 7d are in contact with the coil 6.

In more detail, a right side surface of the second capacitor electrode 73 of each of the capacitors 7a, 7b, 7c, and 7d is in contact with a left side surface of the first coil electrode 62.

The circuit module 1c as described above also achieves the same or substantially the same advantageous effects as those of the circuit module 1. Moreover, the circuit module 1c can further reduce or prevent deviation of each of the capacitors 7a, 7b, 7c, and 7d from a desired position due to heating during soldering. In more detail, the capacitors 7a, 7b, 7c, and 7d are in contact with the coil 6. Accordingly, positional deviation of the capacitors 7a, 7b, 7c, and 7d in the right direction is obstructed by the coil 6. Therefore, the circuit module 1c can further reduce or prevent deviation of each of the capacitors 7a, 7b, 7c, and 7d from a desired position due to heating during soldering.

### Fourth Modification

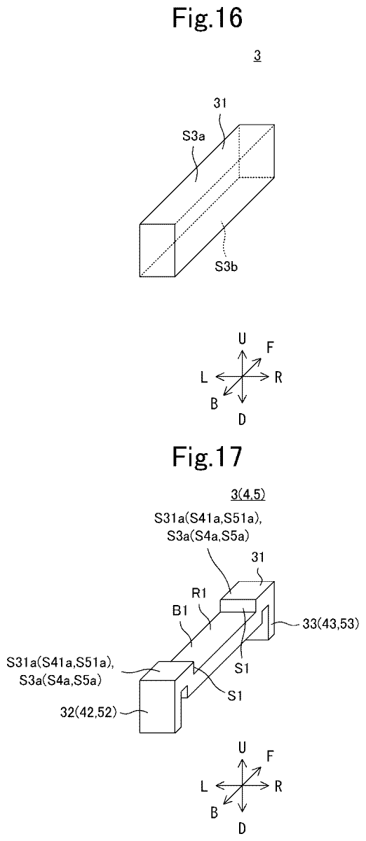

Below, a structure of a circuit module 1d according to a fourth modification of an example embodiment of the present invention is described with reference to the drawing. FIG. 16 is a perspective view of the first conductor 3 according to the fourth modification. The circuit module 1d according to the fourth modification is described only about a portion different from that of the circuit module 1 according to the first example embodiment, and description of the other portions is omitted.

The circuit module 1d according to the fourth modification is different from the circuit module 1 according to the first example embodiment in that each of the first conductor 3, the second conductor 4, and the third conductor 5 has a rectangular or substantially rectangular parallelepiped shape extending in the front-back direction. Structures of the second conductor 4 and the third conductor 5 are the same or substantially the same as a structure of the first conductor 3, and thus description of the structures of the second conductor 4 and the third conductor 5 is omitted.

The first conductor 3 does not include the plate-shaped portion 31, the first support portion 32, and the second support portion 33. The first conductor 3 includes the second upper surface S3a and the second lower surface S3b arranged in the up-down direction.

The circuit module 1d as described above can also reduce or prevent deviation of the capacitor 7a from a desired position due to heating during soldering, similarly to the circuit module 1.

### Fifth Modification

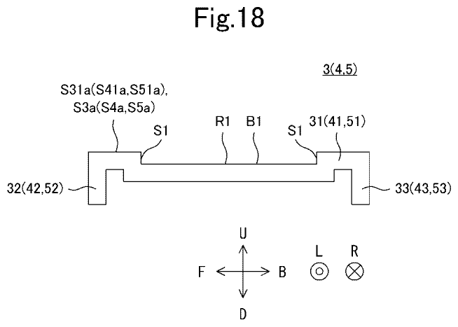

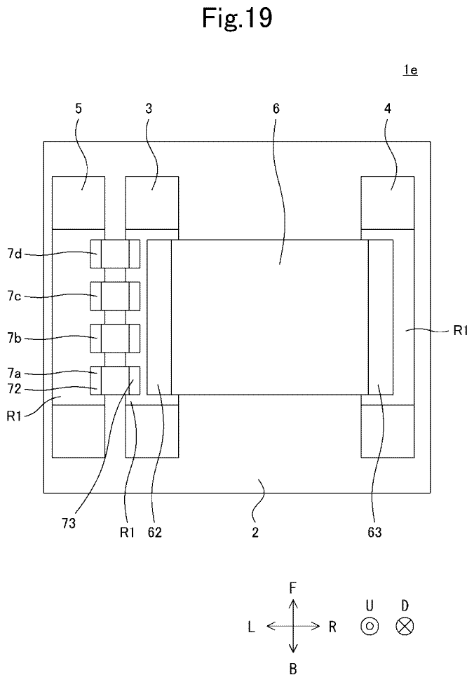

Below, a structure of a circuit module 1e according to a fifth modification of an example embodiment of the present invention is described with reference to the drawings. FIG. 17 is a perspective view of the first conductor 3 (the second conductor 4 or the third conductor 5) according to the fifth modification. FIG. 18 is a sectional view of the first conductor 3 (the second conductor 4 or the third conductor 5) according to the fifth modification when seen in the right direction. FIG. 19 is a plan view of the circuit module 1e according to the fifth modification when seen in the down direction. In FIG. 19, among the plurality of first capacitor electrodes 72 and the plurality of second capacitor electrodes 73, only a representative first capacitor electrode 72 and a representative second capacitor electrode 73 are denoted by reference characters. The circuit module 1e according to the fifth modification is described only about a portion different from that of the circuit module 1 according to the first example embodiment, and description of the other portions is omitted.

The circuit module according to the fifth modification is different from the circuit module 1 according to the first example embodiment in that the first upper surface S31a includes a recess portion R1 recessed in the down direction, the first upper surface S41a includes a recess portion R1 recessed in the down direction, and the first upper surface S51a includes a recess portion R1 recessed in the down direction. In other words, in this modification, the second upper surface S3a includes the recess portion R1 recessed in the down direction. The second upper surface S4a includes the recess portion R1 recessed in the down direction. The second upper surface S5a includes the recess portion R1 recessed in the down direction. Structures of the second conductor 4 and the third conductor 5 are the same or substantially the same as a structure of the first conductor 3, and thus description of the structures of the second conductor 4 and the third conductor 5 is omitted.

As illustrated in FIGS. 17 and 18, in this modification, the recess portion R1 is arranged at a central portion of the first upper surface S31a in the front-back direction. Moreover, when seen in the down direction, the recess portion R1 has a rectangular or substantially rectangular shape including left and right sides extending in the front-back direction and back and front sides extending in the left-right direction. A left end of the recess portion R1 extends to a left end of the first upper surface S31a. In other words, the left side of the recess portion R1 overlaps a left side of the first upper surface S31a when seen in the down direction. A right end of the recess portion R1 extends to a right end of the first upper surface S31a. In other words, the right side of the recess portion R1 overlaps a right side of the first upper surface S31a when seen in the down direction.

In this modification, the recess portion R1 includes a bottom B1 and a side surface S1. In more detail, the bottom B1 is a portion located lowest in the recess portion R1. In this modification, the bottom B1 is a flat surface parallel or substantially parallel to the first upper surface S31a. The side surface S1 couples the first upper surface S31a and the recess portion R1.

As illustrated in FIG. 19, at least a portion of the first coil electrode 62 is provided on the recess portion R1 of the first conductor 3. In this modification, the entirety or substantially entirety of the first coil electrode 62 is provided on the recess portion R1 of the first conductor 3. Moreover, at least a portion of the second coil electrode 63 is provided on the recess portion R1 of the second conductor 4. In this modification, the entirety or substantially the entirety of the second coil electrode 63 is provided on the recess portion R1 of the first conductor 4. In this modification, at least a portion of the first capacitor electrode 72 is provided on the recess portion R1 of the third conductor 5. In more detail, the entirety or substantially the entirety of the first capacitor electrode 72 is provided on the recess portion R1 of the third conductor 5. Moreover, at least a portion of the second capacitor electrode 73 is provided on the recess portion R1 of the first conductor 3. In more detail, the entirety or substantially an entirety of the second capacitor electrode 73 is provided on the recess portion R1 of the first conductor 3.

The circuit module 1e as described above also achieves the same or substantially the same advantageous effects as those of the circuit module 1. Moreover, the circuit module 1e can further reduce or prevent deviation of an electronic component from a desired position due to heating during soldering. In this modification, the electronic component is the coil 6 or each of the capacitors 7a, 7b, 7c, and 7d. Description is provided of the coil 6 as an example.

When soldering is performed to the circuit module 1e, solder provided on each of the second upper surface S3a and the second upper surface S4a is melted by heating. Accordingly, the coil 6 may rotate on the melted solder about a center axis parallel or substantially parallel to an up-down axis and be deviated from the position before the heating. With respect to this, in the circuit module 1e, at least a portion of the first coil electrode 62 is provided on the recess portion R1 of the first conductor 3. Accordingly, rotation of the coil 6 is obstructed by the recess portion R1. In more detail, when the coil 6 rotates certain degrees or greater, the coil 6 contacts the side surface S1 of the recess portion R1 of the first conductor 3, and the coil 6 cannot rotate further. Therefore, the circuit module 1e can reduce or prevent deviation of the coil 6 from the position before the heating. As a result, the circuit module 1e can reduce or prevent deviation of the coil 6 from a desired position due to heating during soldering. The recess portion R1 of the second conductor 4 also achieves the same or substantially the same advantageous effects as those of the recess portion R1 of the first conductor 3. This is applicable not only to the coil 6, but also to the capacitors 7a, 7b, 7c, and 7d in the same or similar manner. Therefore, the circuit module 1e can reduce or prevent deviation of an electronic component from a desired position due to heating during soldering.

### Sixth Modification

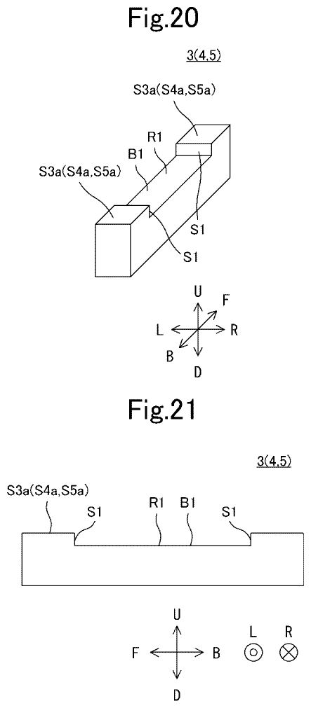

Below, a structure of a circuit module 1f according to a sixth modification of an example embodiment of the present invention is described with reference to the drawings. FIG. 20 is a perspective view of the first conductor 3 (the second conductor 4 or the third conductor 5) according to the sixth modification. FIG. 21 is a sectional view of the first conductor 3 (the second conductor 4 or the third conductor 5) according to the sixth modification when seen in the right direction. The circuit module 1f according to the sixth modification is described only about a portion different from that of the circuit module 1e according to the fifth modification, and description of the other portions is omitted.

The circuit module 1f according to the sixth modification is different from the circuit module 1 according to the fifth modification in that, as illustrated in FIGS. 20 and 21, each of the first conductor 3, the second conductor 4, and the third conductor 5 has a rectangular or substantially rectangular parallelepiped shape extending in the front-back direction. Structures of the second conductor 4 and the third conductor 5 are the same or substantially the same as a structure of the first conductor 3.

The circuit module 1f as described above also achieves the same or substantially the same advantageous effects as those of the circuit module 1e.

### Seventh Modification

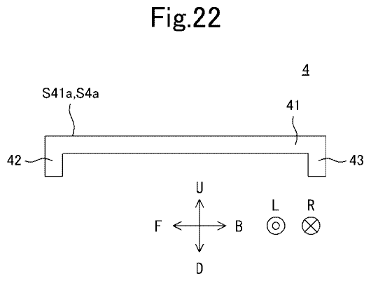

Below, a structure of a circuit module 1g according to a seventh modification of an example embodiment of the present invention is described with reference to the drawing. FIG. 22 is a sectional view of the second conductor 4 according to the seventh modification when seen in the right direction. The circuit module 1g according to the seventh modification is described only about a portion different from that of the circuit module 1e according to the fifth modification, and description of the other portions is omitted.

The circuit module 1g according to the seventh modification is different from the circuit module 1e according to the fifth modification in that, as illustrated in FIG. 22, the first upper surface S41a does not include the recess portion R1 recessed in the down direction.

In this modification, a position of the first upper surface S41a of the second conductor 4 in the up-down direction with respect to the upper main surface S21a of the board main body 21 is the same or substantially the same as a position of the bottom B1 of the first conductor 3 in the up-down direction with respect to the upper main surface S21a of the board main body 21. In other words, a position of the second upper surface S4a of the second conductor 4 in the up-down direction with respect to the upper main surface S21a of the board main body 21 is the same or substantially the same as the position of the bottom B1 of the first conductor 3 in the up-down direction with respect to the upper main surface S21a of the board main body 21.

The circuit module 1g as described above also achieves the same or substantially the same advantageous effects as those of the circuit module 1e. As described in this modification, the first upper surface S41a does not necessarily include the recess portion R1 recessed in the down direction. Also in this case, at least a portion of the first coil electrode 62 is provided on the recess portion R1 of the first conductor 3. Similarly, the first upper surface S51a does not necessarily include the recess portion R1 recessed in the down direction. Also in this case, at least portion of the first coil electrode 62 is provided on the recess portion R1 of the first conductor 3.

The first upper surface S31a does not necessarily include the recess portion R1 recessed in the down direction. In this case, at least a portion of the second coil electrode 63 is provided on the recess portion R1 of the second conductor 4. Accordingly, when the coil 6 rotates certain degrees or greater, the coil 6 contacts the side surface S1 of the recess portion R1 of the second conductor 4, and the coil 6 cannot rotate further. Therefore, deviation of the coil 6 from a desired position due to heating during soldering can be reduced or prevented. That is, either of the first upper surface S31a of the first conductor 3 and the first upper surface S41a of the second conductor 4 includes the recess portion R1 recessed in the down direction. In other words, either of the second upper surface S3a of the first conductor 3 and the second upper surface S4a of the second conductor 4 includes the recess portion R1 recessed in the down direction. Accordingly, deviation of the coil 6 from a desired position due to heating during soldering can be reduced or prevented.

Moreover, at least a portion of the first capacitor electrode 72 may be provided on the recess portion R1 of the third conductor 5. Description is provided of the capacitor 7a as an example. When the capacitor 7a rotates certain degrees or greater, the capacitor 7a contacts the side surface S1 of the recess portion R1 of the third conductor 5, and the capacitor 7a cannot rotate further. Therefore, deviation of the capacitor 7a from a desired position due to heating during soldering can be reduced or prevented. This is applicable not only to the capacitor 7a, but also to the capacitors 7b, 7c, and 7d in the same or similar manner. That is, either of the first upper surface S31a of the first conductor 3 and the first upper surface S51a of the third conductor 5 includes the recess portion R1 recessed in the down direction. In other words, either of the second upper surface S3a of the first conductor 3 and the second upper surface S5a of the third conductor 5 includes the recess portion R1 recessed in the down direction. Accordingly, deviation of each of the capacitors 7a, 7b, 7c, and 7d from a desired position due to heating during soldering can be reduced or prevented.

### Other Example Embodiments

The circuit modules according to example embodiments of the present invention are not limited to the circuit modules 1 and 1a to 1g described above, but are changeable within a scope of the present invention. Moreover, the structures of the circuit modules 1 and 1a to 1g may be included in any combination.

The circuit module 1 and 1a to 1g according to an example embodiment of the present invention may further include an IC (integrated circuit). Moreover, a power conversion system including at least one of the circuit module 1 and 1a to 1g according to an example embodiment of the present invention. For example, the power conversion system may include at least one circuit module 1 and 1a to 1g, a switch device SW, and a diode D. For example, the power conversion system may include at least one circuit module 1 and 1a to 1g, a rectifier CON, and an inverter INV.

The circuit module 1 does not necessarily include the third conductor 5 and the capacitors 7a, 7b, 7c, and 7d.

When the circuit module 1 includes a capacitor, the number of capacitors is one or more.

The first board electrodes 22a and 22b are not necessarily arranged in this order from the back to the front. The second board electrodes 23a and 23b are not necessarily arranged in this order from the back to the front. The third board electrodes 24a and 24b are not necessarily arranged in this order from the back to the front.

The third board electrode 24a, the first board electrode 22a, and the second board electrode 23a are not necessarily arranged in this order from the left to the right. The third board electrode 24b, the first board electrode 22b, and the second board electrode 23b are not necessarily arranged in this order from the left to the right.

The third conductor 5, the first conductor 3, and the second conductor 4 are not necessarily arranged in this order from the left to the right.

Each of the plate-shaped portion 31, the plate-shaped portion 41, and the plate-shaped portion 51 does not necessarily have a rectangular or substantially rectangular shape.

Each of the first support portions 32, 42, and 52, the second support portions 33, 43, and 53, and the main body 61 does not necessarily have a rectangular or substantially rectangular parallelepiped shape.

The first coil electrode 62 and the second coil electrode 63 are not necessarily arranged in this order from the left to the right.

The first capacitor electrode 72 and the second capacitor electrode 73 are not necessarily arranged in this order from the left to the right.

The entirety or substantially the entirety of the first coil electrode 62 may be provided on the first region A1 of the first upper surface S31a.

A portion of the second coil electrode 63 may be provided on the second region A2 of the first upper surface S41a.

The recess portion R1 of the first conductor 3 is not necessarily arranged at the center of the first upper surface S31a in the front-back direction. The recess portion R1 of the second conductor 4 is not necessarily arranged at the center of the first upper surface S41a in the front-back direction. The recess portion R1 of the third conductor 5 is not necessarily arranged at the center of the first upper surface S51a in the front-back direction.

The recess portion R1 does not necessarily have a rectangular or substantially rectangular shape when seen in the down direction.

The recess portion R1 does not necessarily include the side surface S1. For example, the recess portion R1 may have a shape recessed to be curved in the down direction.

The bottom B1 is not necessarily a flat surface parallel or substantially parallel to the first upper surface S31a.

In the circuit module 1c, at least one of the capacitors 7a, 7b, 7c, and 7d is in contact with the coil 6. In this case, deviation of the capacitor in contact with the coil 6 from a desired position due to heating during soldering can be reduced or prevented.

In the circuit module 1e, at least a portion of the first capacitor electrode 72 is not necessarily provided on the recess portion R1 of the third conductor 5. At least a portion of the second capacitor electrode 73 is not necessarily provided on the recess portion R1 of the first conductor 3.

In the circuit module 1g, the position of the first upper surface S41a of the second conductor 4 in the up-down direction with respect to the upper main surface S21a of the board main body 21 is not necessarily the same or substantially the same as the position of the bottom B1 of the first conductor 3 in the up-down direction with respect to the upper main surface S21a of the board main body 21.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A power conversion circuit module comprising:
a circuit board including:
a board main body including an upper main surface and a lower main surface arranged in an up-down direction; and
one or more board electrodes on the upper main surface;
a coil including a first coil electrode and a second coil electrode;
one or more capacitors each including a first capacitor electrode and a second capacitor electrode;
a first conductor electrically coupling one of the one or more board electrodes to each of the first coil electrode and the second capacitor electrode;
a second conductor electrically coupling another one of the one or more board electrodes to the second coil electrode; and
a third conductor electrically coupling another one of the one or more board electrodes to the first capacitor electrode; wherein
a mass of the coil is larger than a mass of each of the one or more capacitors;
each of the first conductor, the second conductor, and the third conductor includes a second upper surface and a second lower surface arranged in the up-down direction;
each of the first coil electrode and the second capacitor electrode is provided on the second upper surface of the first conductor;
the second coil electrode is provided on the second upper surface of the second conductor; and
the first capacitor electrode is provided on the second upper surface of the third conductor.

2. The power conversion circuit module according to claim 1, wherein a number of the one or more capacitors is two or more.

3. The power conversion circuit module according to claim 1, wherein
the first conductor includes:
a plate-shaped portion extending in a front-back direction and including a first upper surface and a first lower surface arranged in the up-down direction;
a first support portion extending in a down direction from a rear end portion of the first lower surface of the plate-shaped portion; and
a second support portion extending in the down direction from a front end portion of the first lower surface of the plate-shaped portion;
when seen in the down direction, the first upper surface of the first conductor includes a first region not overlapping one of the first support portion of the first conductor and the second support portion of the first conductor;
at least one of the first support portion of the first conductor or the second support portion of the first conductor is provided on the one of the one or more board electrodes; and
at least a portion of the first coil electrode is provided on the first region.

4. The power conversion circuit module according to claim 1, wherein
the second upper surface of the first conductor includes a recess portion recessed in a down direction; and
at least a portion of the first coil electrode is provided on the recess portion of the first conductor.

5. The power conversion circuit module according to claim 1, wherein at least one of the one or more capacitors is in contact with the coil.

6. The power conversion circuit module according to claim 1, wherein
the coil includes a main body having a rectangular or substantially rectangular parallelepiped shape; and
each of the first coil electrode and the second coil electrode is provided to a surface of the main body.

7. The power conversion circuit module according to claim 1, wherein each of the one or more capacitors is an output capacitor of a buck converter.

8. A power conversion system comprising the power conversion circuit module according to claim 1.

9. The power conversion system according to claim 8, wherein a number of the one or more capacitors is two or more.

10. The power conversion system according to claim 8, wherein
the first conductor includes:
a plate-shaped portion extending in a front-back direction and including a first upper surface and a first lower surface arranged in the up-down direction;
a first support portion extending in a down direction from a rear end portion of the first lower surface of the plate-shaped portion; and
a second support portion extending in the down direction from a front end portion of the first lower surface of the plate-shaped portion;
when seen in the down direction, the first upper surface of the first conductor includes a first region not overlapping one of the first support portion of the first conductor and the second support portion of the first conductor;
at least one of the first support portion of the first conductor or the second support portion of the first conductor is provided on the one of the one or more board electrodes; and
at least a portion of the first coil electrode is provided on the first region.

11. The power conversion system according to claim 8, wherein
the second upper surface of the first conductor includes a recess portion recessed in a down direction; and
at least a portion of the first coil electrode is provided on the recess portion of the first conductor.

12. The power conversion system according to claim 8, wherein at least one of the one or more capacitors is in contact with the coil.

13. The power conversion system according to claim 8, wherein
the coil includes a main body having a rectangular or substantially rectangular parallelepiped shape; and
each of the first coil electrode and the second coil electrode is provided to a surface of the main body.

14. The power conversion system according to claim 8, wherein each of the one or more capacitors is an output capacitor of a buck converter.

15. A power conversion circuit module comprising:
a circuit board including:
a board main body including an upper main surface and a lower main surface arranged in an up-down direction; and
one or more board electrodes on the upper main surface;
a coil including a first coil electrode; and
a first conductor electrically coupling one of the one or more board electrodes to the first coil electrode; wherein
the first conductor includes:
a plate-shaped portion extending in a front-back direction and including a first upper surface and a first lower surface arranged in the up-down direction;
a first support portion extending in a down direction from a rear end portion of the first lower surface; and
a second support portion extending in the down direction from a front end portion of the first lower surface;
when seen in the down direction, the first upper surface of the first conductor includes a first region not overlapping one of the first support portion of the first conductor and the second support portion of the first conductor;
at least one of the first support portion of the first conductor or the second support portion of the first conductor is provided on the one of the one or more board electrodes, and at least a portion of the first coil electrode is provided on the first region.

16. The power conversion circuit module according to claim 15, further comprising:
a second conductor; wherein
the coil includes a second coil electrode;
the second conductor electrically couples another one of the one or more board electrodes to the second coil electrode;
the second conductor includes:
a plate-shaped portion extending in the front-back direction and including a first upper surface and a first lower surface arranged in the up-down direction;
a first support portion extending in the down direction from a rear end portion of the first lower surface of the second conductor; and
a second support portion extending in the down direction from a front end portion of the first lower surface of the second conductor;
when seen in the down direction, the first upper surface of the second conductor includes a second region not overlapping one of the first support portion of the second conductor and the second support portion of the second conductor;
at least one of the first support portion of the second conductor or the second support portion of the second conductor is provided on the another one of the one or more board electrodes; and
at least a portion of the second coil electrode is provided on the second region.

17. The power conversion circuit module according to claim 15, wherein
the first upper surface of the first conductor includes a recess portion recessed in the down direction; and
at least a portion of the first coil electrode is provided on the recess portion of the first conductor.

18. A power conversion system comprising the power conversion circuit module according to claim 15.

19. The power conversion system according to claim 18, further comprising:
a second conductor; wherein
the coil includes a second coil electrode;
the second conductor electrically couples another one of the one or more board electrodes to the second coil electrode;
the second conductor includes:
a plate-shaped portion extending in the front-back direction and including a first upper surface and a first lower surface arranged in the up-down direction;
a first support portion extending in the down direction from a rear end portion of the first lower surface of the second conductor; and
a second support portion extending in the down direction from a front end portion of the first lower surface of the second conductor;
when seen in the down direction, the first upper surface of the second conductor includes a second region not overlapping one of the first support portion of the second conductor and the second support portion of the second conductor;
at least one of the first support portion of the second conductor or the second support portion of the second conductor is provided on the another one of the one or more board electrodes; and
at least a portion of the second coil electrode is provided on the second region.

20. The power conversion system according to claim 18, wherein
the first upper surface of the first conductor includes a recess portion recessed in the down direction; and
at least a portion of the first coil electrode is provided on the recess portion of the first conductor.
